(19) United States
(12) Patent Application Publication
(10) Pub. No.: US 2025/0273424 A1
(43) Pub. Date: Aug. 28, 2025

(54) USE OF MULTIPLE ELECTRON BEAMS FOR HIGH THROUGHPUT INSPECTION

(71) Applicant: KLA Corporation, Milpitas, CA (US)

(72) Inventors: Xinrong Jiang, Palo Alto, CA (US); Youfei Jiang, Milpitas, CA (US); Sameet Shriyan, Milpitas, CA (US)

(21) Appl. No.: 18/590,930

(22) Filed: Feb. 28, 2024

(51) Int. Cl. H01J 37/10; H01J 37/147

(52) U.S. Cl. CPC H01J 37/10; H01J 37/1474; H01J 2237/0435

(57) ABSTRACT

A telecentric charged particle beam, which can be an electron beam, is directed through an array of apertures to divide the telecentric charged particle beam to a plurality of telecentric illumination beamlets. The telecentric illumination beamlets through an imaging lens, a field lens at an intermediate image plane, and a transfer lens. The telecentric illumination beamlets are scanned as the telecentric illumination beamlets are directed through an upper scan deflector and a lower scan deflector and directed onto a workpiece on a stage.

### FIELD OF THE DISCLOSURE

This disclosure relates to electron beam systems and, more particularly, inspection of workpieces using electron beams or other charged particle beams.

### BACKGROUND OF THE DISCLOSURE

Evolution of the semiconductor manufacturing industry is placing greater demands on yield management and, in particular, on metrology and inspection systems. Critical dimensions continue to shrink, yet the industry needs to decrease time for achieving high-yield, high-value production. Minimizing the total time from detecting a yield problem to fixing it maximizes the return-on-investment for a semiconductor manufacturer.

Fabricating semiconductor devices, such as logic and memory devices, typically includes processing a workpiece, such as a semiconductor wafer, using a large number of fabrication processes to form various features and multiple levels of the semiconductor devices. For example, lithography is a semiconductor fabrication process that involves transferring a pattern from a reticle to a photoresist arranged on a semiconductor wafer. Additional examples of semiconductor fabrication processes include, but are not limited to, chemical-mechanical polishing (CMP), etching, deposition, and ion implantation. An arrangement of multiple semiconductor devices fabricated on a single semiconductor wafer may be separated into individual semiconductor devices.

Inspection processes are used at various steps during semiconductor manufacturing to detect defects on workpieces to promote higher yield in the manufacturing process and, thus, higher profits. Inspection has always been an important part of fabricating semiconductor devices such as integrated circuits (ICs). However, as the dimensions of semiconductor devices decrease, inspection becomes even more important to the successful manufacture of acceptable semiconductor devices because smaller defects can cause the devices to fail. For instance, as the dimensions of semiconductor devices decrease, detection of defects of decreasing size has become necessary because even relatively small defects may cause unwanted aberrations in the semiconductor devices.

As design rules shrink, however, semiconductor manufacturing processes may be operating closer to the limitation on the performance capability of the processes. In addition, smaller defects can have an impact on the electrical parameters of the device as the design rules shrink, which drives more sensitive inspections. As design rules shrink, the population of potentially yield-relevant defects detected by inspection grows dramatically, and the population of nuisance defects detected by inspection also increases dramatically. Therefore, more defects may be detected on the workpieces, and correcting the processes to eliminate all of the defects may be difficult and expensive. Determining which of the defects actually have an effect on the electrical parameters of the devices and the yield may allow process control methods to be focused on those defects while largely ignoring others. Furthermore, at smaller design rules, process-induced failures, in some cases, tend to be systematic. That is, process-induced failures tend to fail at predetermined design patterns often repeated many times within the design. Elimination of spatially-systematic, electrically-relevant defects can have an impact on yield.

Scanning electron beam inspection tools can be used to inspect semiconductor devices on workpieces, like semiconductor wafers. Commercially-available electron beam-based inspection tools currently use a single electron beam column that scans across the workpiece. This has low throughput, which is an obstacle for adoption because the images are acquired pixel-by-pixel in a sequential manner. The scan field of view (FOV) of a single electron beam is only tens of microns wide due to optical blurs and distortion. The motions of the stage holding the workpiece may need to inspect an integrated circuit die with a size measured in millimeters to tens of millimeters. Performing many stage motions will further lower the throughput. The low throughput with a single electron beam raises inspection costs.

Workpiece inspection with an apparatus that generates multiple electron beams has been used for examining semiconductor chip defects. The semiconductor defects on a fabricated wafer are commonly examined within an integrated circuit die. The defects are found by comparing the inspection signals against the standard signals without defects.

FIG. 1 illustrates a square multiple electron beam array with, for instance, 400 (20×20) electron beamlets separated by a pitch distance p (e.g., p=10 microns). These electron beamlets are image-formed on a being-fabricated workpiece (e.g., wafer) with a spot size (SS) in a range of nanometers to tens of nanometers. The spot size stands for the resolution of an electron beam apparatus. The smaller the spot size, the higher the resolution will be.

The FOV of an apparatus with multiple electron beams on a workpiece (i.e. FOVᵢ) may be hundreds of microns. For instance, the FOVᵢ in FIG. 1 is 190 μm with a pitch of p=10 μm for 400 electron beamlets. All electron beamlets in FIG. 1 are collectively-scanned over the workpiece in a scan-field (SF) of p×p (i.e., 10×10 microns). Including the scan-field area, the total FOV in FIG. 1 may be 200×200 microns.

The size of an IC die may range from approximately 1×1 mm² to approximately 100×100 mm². In an example, an IC die of 10×10 mm² is 2500× larger than an FOV of 200×200 microns. This means that the stage holding the workpiece moves 2500 times to complete the electron beam inspection (EBI) across a full IC die. A stage motion from one FOV to another FOV may take less than one second, meaning inspection may take about 17 minutes in a typical specification of 0.4 seconds.

Workpiece EBI performance is typically characterized by the relation between the resolution and throughput. The EBI throughput (TPT) is defined with the time to examine a full IC die. The shorter the time, the higher the throughput. For a higher throughput, more electron beamlets with larger FOVs (i.e., less stage motion times) may be needed.

The electron beamlet resolution is defined with the spot size in FIG. 1. The spot size includes many components, such as the imaging blurs due to lensing effects and electron-electron interaction blurs due to Coulomb effects. The imaging blurs are dominated by the off-axis blurs, such as the Coma blur, the field curvature (FC) blur, the astigmatism (stig) blur, and the transverse chromatic (TC) blur, described below.

$$Coma ∝ {C}_{coma} * {FOV}_{i} * {β}^{2} \qquad ( 1 )$$

$$FC ∝ {C}_{FC} * {FOV}_{i}^{2} {*}_{←}^{\to } β \qquad ( 2 )$$

$$Stig ∝ {C}_{stig} * {FOV}_{i}^{2} * β \qquad ( 3 )$$

$$TC ∝ {C}_{TC} * {FOV}_{i} * \frac{Δ E}{LE} \qquad ( 4 )$$

In Equations (1)-(4), B is the numeric aperture of a beamlet in the wafer, ΔE is the electron source energy spread, and LE is the landing energy of a beamlet on the workpiece. The coefficients C_{coma}, C_{FC}, C_{stig}, and C_{TC} are given by the optical configuration of an apparatus with multiple electron beams. Besides the off-axis blurs, the off-axis beamlet distortion may be more affected by the FOVᵢ.

$$Distortion ∝ {C}_{dist} * {FOV}_{i}^{3} \qquad ( 5 )$$

In Equation (5), the C_{dist} is the distortion coefficient. The off-axis blurs (Coma, FC, Stig, and TC) and distortion limit the imaging uniformity of the electron beamlets across an FOVᵢ on a workpiece (i.e., the machine throughput). These can be limited in an acceptable specification to avoid incorrectly detecting defects in wafer EBI operations.

Improved systems and techniques for inspection with electron beams are needed.

### BRIEF SUMMARY OF THE DISCLOSURE

An apparatus is provided in a first embodiment. The apparatus includes a source that generates a telecentric charged particle beam; a stage configured to hold a workpiece in a path of a plurality of telecentric illumination beamlets; and an array of apertures disposed in a path of the telecentric charged particle beam between the source and the stage. The array of apertures is configured to divide the telecentric charged particle beam into the plurality of telecentric illumination beamlets. A field lens is disposed in the path of the telecentric illumination beamlets at an intermediate image plane. A transfer lens is disposed in the path of the telecentric illumination beamlets between the field lens and the stage. An imaging lens is disposed in the path of the telecentric illumination beamlets between the source and the field lens. An upper scan deflector is disposed in the path of the telecentric illumination beamlets between the transfer lens and the stage. A lower scan deflector is disposed in the path of the telecentric illumination beamlets between the upper scan deflector and the stage. The upper scan deflector and the lower scan deflector are configured to scan the telecentric illumination beamlets.

The apparatus can include a micro deflector array disposed in the path of the telecentric illumination beamlets between the array of apertures and the imaging lens; a micro stigmator array disposed in the path of the telecentric illumination beamlets between the micro deflector array and the imaging lens; and a field curvature corrector disposed in the path of the telecentric illumination beamlets between the micro stigmator array and the imaging lens.

The telecentric illumination beamlets can be configured to have a first crossover along the path of the telecentric illumination beamlets between the imaging lens and the field lens. The telecentric illumination beamlets can be configured to have a second crossover along the path of the telecentric illumination beamlets between the lower scan deflector and the stage. In an instance, the telecentric illumination beamlets have an angle at the first crossover configured to reduce Coulomb interaction.

The field lens may be a magnetic field lens. In an instance, the imaging lens is a magnetic imaging lens. The apparatus can further include a fixed voltage electrode disposed in the path of the telecentric illumination beamlets between the field curvature corrector and the magnetic imaging lens and a multi-beam splitter electrode disposed in the path of the telecentric illumination beamlets between the fixed voltage electrode and the magnetic imaging lens.

The telecentric illumination beamlets can be focused on the intermediate image plane using global electrostatic fields or global magnetic fields.

In an embodiment, the telecentric charged particle beam is a telecentric electron beam and the source is an electron beam source.

A method is provided in a second embodiment. The method includes generating a telecentric charged particle beam with a source. The telecentric charged particle beam is directed through an array of apertures. The array of apertures is configured to divide the telecentric charged particle beam to a plurality of telecentric illumination beamlets. The telecentric illumination beamlets are directed through an imaging lens downstream of the array of apertures along a path of the telecentric illumination beamlets. The telecentric illumination beamlets are directed through a field lens downstream of the imaging lens along the path of the telecentric illumination beamlets. The field lens is at an intermediate image plane. The telecentric illumination beamlets are directed through a transfer lens disposed downstream of the field lens along the path of the telecentric illumination beamlets. The telecentric illumination beamlets are scanned as the telecentric illumination beamlets are directed through an upper scan deflector and a lower scan deflector disposed downstream of the transfer lens along the path of the telecentric illumination beamlets. The telecentric illumination beamlets are directed onto a workpiece on a stage disposed downstream of the lower scan deflector along the path of the telecentric illumination beamlets.

The method can include directing the telecentric illumination beamlets through a micro deflector array downstream of the array of apertures along the path of the telecentric illumination beamlets; directing the telecentric illumination beamlets through a micro stigmator array downstream of the micro deflector array along the path of the telecentric illumination beamlets; and directing the telecentric illumination beamlets through a field curvature corrector downstream of the micro stigmator array along the path of the telecentric illumination beamlets. The field curvature corrector may be disposed upstream of the imaging lens along the path of the telecentric illumination beamlets. In an instance, field curvatures caused by the image lens can be corrected using the field curvature corrector. In another instance, field curvatures caused by the transfer lens, the upper scan deflector, and the lower scan deflector can be corrected using the field curvature corrector.

The telecentric illumination beamlets may be configured to have a first crossover along the path of the telecentric illumination beamlets between the imaging lens and the field lens. The telecentric illumination beamlets can be configured to have a second crossover along the path of the telecentric illumination beamlets between the lower scan deflector and the stage. In an instance, the telecentric illumination beamlets can have an angle at the first crossover configured to reduce Coulomb interaction.

The field lens may be a magnetic field lens. In an instance, the imaging lens is a magnetic imaging lens and the method includes directing the telecentric illumination beamlets through a fixed voltage electrode disposed in the path of the telecentric illumination beamlets between the field curvature corrector and the magnetic imaging lens and directing the telecentric illumination beamlets through a multi-beam splitter electrode disposed in the path of the telecentric illumination beamlets between the fixed voltage electrode and the magnetic imaging lens.

The telecentric illumination beamlets can have an off-axis blur of less than 5 nm as the telecentric illumination beamlets are directed onto the workpiece.

The telecentric illumination beamlets can have a distortion of less than one pixel size as the telecentric illumination beamlets are directed onto the workpiece.

The telecentric illumination beamlets may be focused on the intermediate image plane using global electrostatic fields or global magnetic fields.

In an embodiment, the telecentric charged particle beam is a telecentric electron beam and the source is an electron beam source.

### DESCRIPTION OF THE DRAWINGS

For a fuller understanding of the nature and objects of the disclosure, reference should be made to the following detailed description taken in conjunction with the accompanying drawings, in which:

FIG. 1 shows inspection of a workpiece with an array of multiple electron beams;

FIG. 2 is a block diagram of an electron beam apparatus is accordance with the present disclosure;

FIG. 3 shows use of a electrostatic image lens with multiple electron beams

FIG. 4 shows an electron ray-tracing simulation for creating of multiple electron beams;

FIG. 5 is a schematic diagram of an embodiment for correcting field curvature;

FIG. 6 is a chart showing off-axis blurs with the electron beam apparatus of FIG. 2;

FIG. 7 is a chart showing correction of field curvatures using an FCC;

FIG. 8 is a schematic diagram showing transverse chromatic (TC) blurs;

FIG. 9 shows use of a magnetic image lens with multiple electron beams;

FIG. 10 is an exemplary electron trajectory simulation for showing multiple electron beam creation and image formation with a magnetic image lens;

FIG. 11(a)-(b) shows TC and coma blurs for a 20×20 (400) beam array with a pitch of 100 microns; and

FIG. 12 is a chart showing throughput scaling with a fixed pitch between beamlet separations.

### DETAILED DESCRIPTION OF THE DISCLOSURE

Although claimed subject matter will be described in terms of certain embodiments, other embodiments, including embodiments that do not provide all of the benefits and features set forth herein, are also within the scope of this disclosure. Various structural, logical, process step, and electronic changes may be made without departing from the scope of the disclosure. Accordingly, the scope of the disclosure is defined only by reference to the appended claims.

Inspection tools with multiple electron beams can improve the throughput of wafer inspections. Optics for multiple electron beams tend to be a projection optics in which the off-axis optical blurs (coma, field curvature, astigmatism, and transverse chromatic aberration) and distortion increase with the larger FOVs or more electron beamlets associated with higher throughputs. To maintain high resolution when improving the throughputs across a large FOV, these off-axis blurs and distortion may need to be either corrected or reduced.

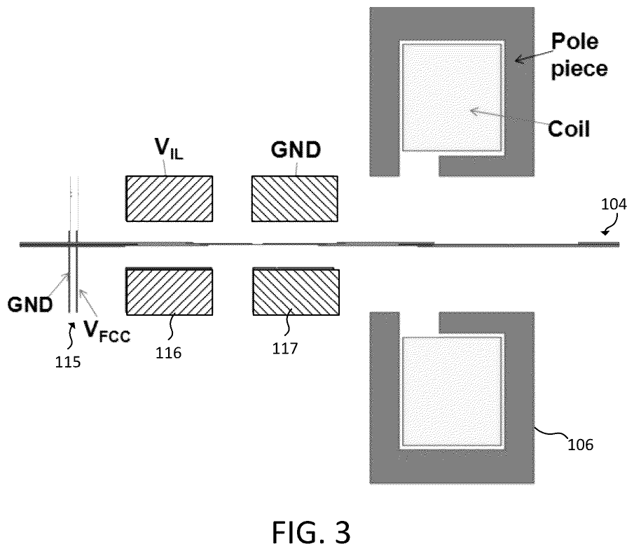

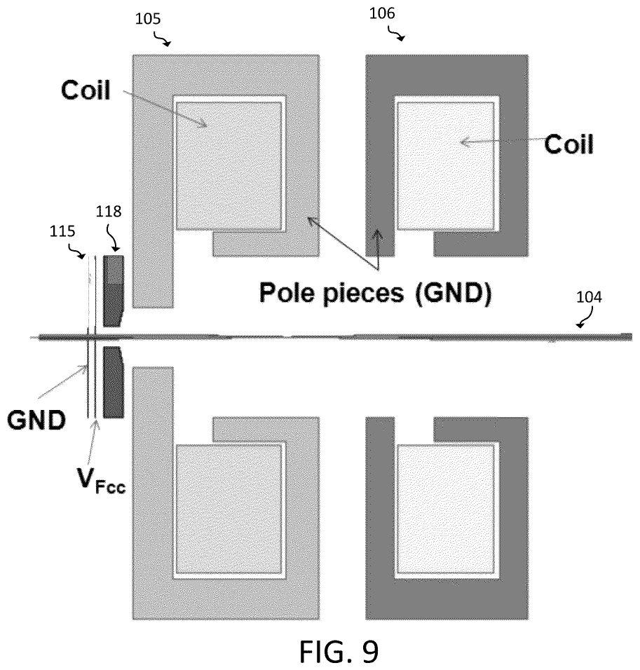

Embodiments disclosed herein can remove the field curvature, astigmatism, and distortion by using optical corrections. The transverse chromatic aberration can be reduced 2.5× by using a magnetic technique to create and image the multiple electron beams. The uncorrectable coma blur can be reduced through optimization of optical configuration. Consequently, the FOV can be increased 2× or the throughput can be increased 4×. Creating and imaging multiple electron beams with a magnetic imaging lens (FIG. 9) can be better to that with an electrostatic imaging lens (FIG. 3), but either design can be used. The magnetic imaging lens reduces the TC blur (e.g., by 2.5×) and avoids high voltages like the electrostatic imaging lens. Using global electrostatic or magnetic fields to focus multiple electron beams (MEB) on the intermediate image plane (IIP) can remove severe spherical aberrations with arrayed lenses. Using a global field curvature corrector (FCC) voltage can correct not only the image lens (IL)-induced field curvatures (FCs), but also the FCs generated in the lower column from the IIP to workpiece. Both the electrostatic image lens and magnetic image lens generate FCs, but the latter produces fewer FCs. The global FCC can correct both FCs, but using lower FCC voltages for the latter can provide fewer FCs. Using large angles of MEB crossover (xo1) can minimize the influence of Coulomb interaction between electrons on MEB resolutions. Consequently, the beam crossover may be moved closer to workpiece to reduce Coulomb interactions if using a magnetic image lens. Normally the closer the crossover is to the workpiece, the larger the total FC will be. It becomes possible to have the crossover closer to workpiece because of lower FCs with a magnetic image lens.

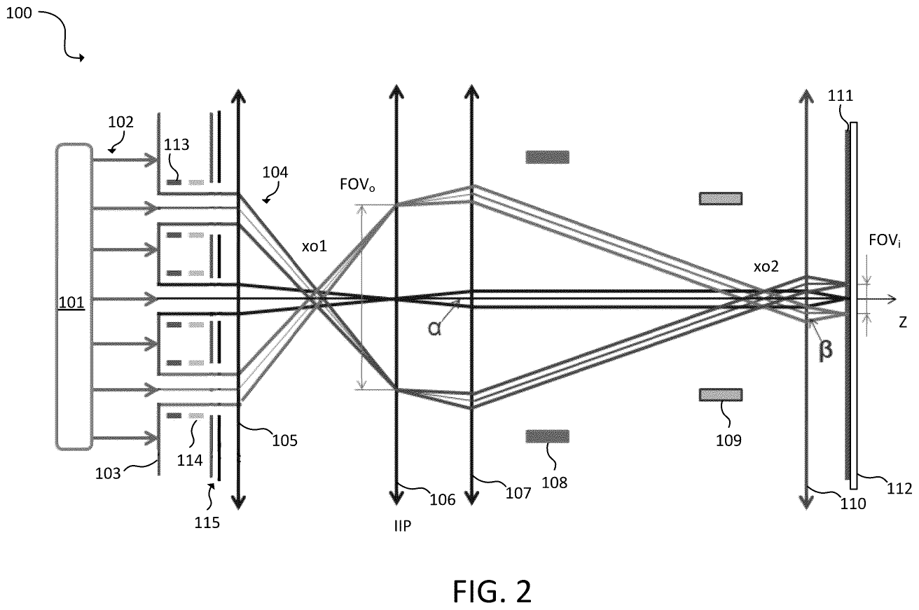

FIG. 2 shows the optical architecture of an electron beam apparatus 100. The electron beam apparatus 100 includes an electron source 101 that generates at least one telecentric electron beam 102. Multiple arrows signify one larger telecentric electron beam 102, though multiple telecentric electron beams 102 are possible. The electron source 101 may be a thermal field emission (TFE) source with high brightness and/or high angular intensity (e.g., around 1.0 mA/sr). The source-emitted electrons with high total beam currents (e.g., tens of micro-Amperes) can be focused with a gun lens and/or collimated lens (not shown in FIG. 2) to form a telecentric electron beam 102, such as a telecentric illumination beam (TIB). In an embodiment, a total illumination beam current can be in the tens of uAs, angular intensity can be approximately 1.0 mA/sr, beam energy can be approximately 30 kV, and a beam size can be approximately 2 mm in diameter.

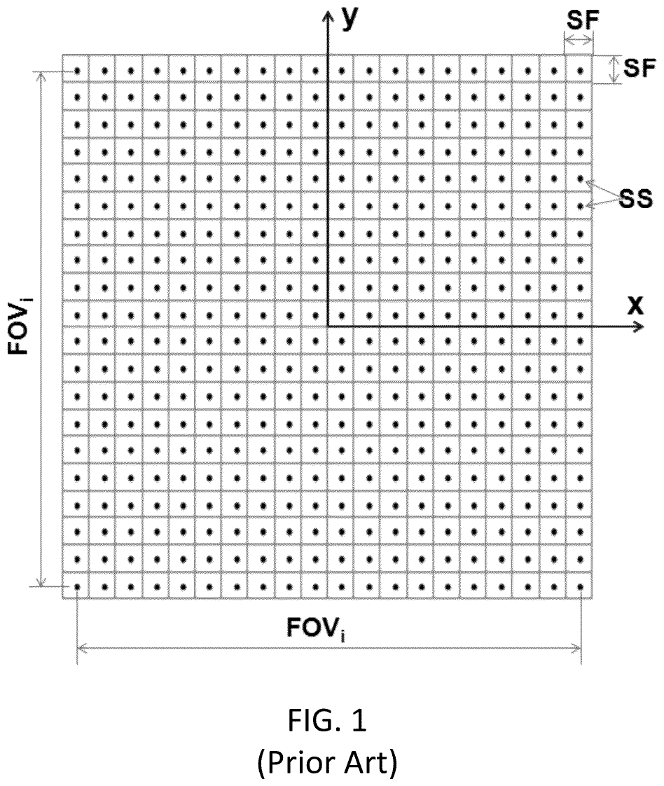

An array of apertures (AA) 103 is disposed in the path of the telecentric electron beam 102 between the electron source 101 and the stage 112 The array of apertures 103 is configured to divide the telecentric electron beam 102 to the plurality of electron beams, such as from 100 to 400 beamlets 104. The array of apertures 103 may be similar to FIG. 1 if the aperture hole sizes is used to replace the spot sizes. The apertures in the array of apertures 103 can be, for example, square or polygonal (e.g., hexagonal) with a uniform spacing. The array of apertures 103 divides the large TIB into many small telecentric illumination beamlets 104. The telecentric illumination beamlets 104 are smaller than the original telecentric illumination beam, but each can be considered as an electron beam.

These telecentric illumination beamlets 104 are then independently focused through a beam crossover of xo1 on an intermediate image plane (IIP) by a global imaging lens (IL) 105. Thus, the telecentric illumination beamlets 104 can be focused on the intermediate image plane using global electrostatic fields or global magnetic fields. The global imaging lens 105 is disposed in the path of the telecentric illumination beamlets 104 between the electron source 101 and the global field lens 106. A global field lens (FL) 106 is used to adjust the directions of the telecentric illumination beamlets 104. The field lens 106 is disposed in the path of the telecentric illumination beamlets 104 at an intermediate image plane. The principal plane of the global field lens 106 can be deployed in the IIP plane for adjustment purpose of the telecentric illumination beamlet 104 directions without changing the image-forming relation of each beamlet 104. A global transfer lens (TL) 107 can be used to focus the telecentric illumination beamlets 104 and form a second beam crossover (xo2) around the back focal plane of the global objective lens (OL) 110. The global transfer lens 107 is disposed in the path of the telecentric illumination beamlets 104 between the field lens 106 and the stage 112. The global objective lens 110 image-forms the telecentric illumination beamlets 104 on the workpiece 111. The workpiece 111 is held in the path of the telecentric illumination beamlets using a stage 112, as shown in FIG. 2. The optics from the IIP to workpiece 111 is a projection optics characterized by an optical magnification (e.g., M=FOVᵢ/FOVₒ in FIG. 2), and the multi beam array in the intermediate image plane may be evaluated with the optical magnification M (e.g., approximately 0.1×).

The telecentric illumination beamlets 104 are collective-scanned by the dual-deflector system consisting of the upper scan deflector (USD) 108 and lower scan deflector (LSD) 109. The upper scan deflector 108 is disposed in the path of the telecentric illumination beamlets 104 between the transfer lens 107 and the stage 112. The lower scan deflector 109 is disposed in the path of the telecentric illumination beamlets 104 between the upper scan deflector 108 and the stage 112. This dual-deflector system can lower deflection aberrations across a scan field (SF) in FIG. 1. The deflection aberrations are normally the off-axis aberrations. Using one deflector, the beamlets 104 are off-axis when they are passing through the objective lens 110, causing the off-axis aberrations. Using two deflectors, the beamlets 104 can be directed to pass through the objective lens 110 center, minimizing the off-axis distance and minimizing the off-axis aberrations while still scanning the beams with an FOV.

In an instance, the upper and lower deflectors 108, 109 are electrostatic deflectors for high scanning speed. For example, the upper and lower deflectors 108, 109 can be electrostatic octupole deflectors for uniform deflection fields and low deflection aberrations.

As shown in FIG. 2, the electron beam apparatus 100 can include a micro deflector array 113 disposed in the path of the telecentric illumination beamlets 104 between the array of apertures 103 and the imaging lens 105 and a micro stigmator array 114 disposed in the path of the telecentric illumination beamlets 104 between the micro deflector array 113 and the imaging lens 105. A field curvature corrector 115 can be disposed in the path of the telecentric illumination beamlets 104 between the micro stigmator array 114 and the imaging lens 105.

The telecentric illumination beamlets 104 can be configured to have a first crossover along the path of the telecentric illumination beamlets 104 between the imaging lens 105 and the field lens 106 and a second crossover along the path of the telecentric illumination beamlets 104 between the lower scan deflector 109 and the stage 112. In an instance, the telecentric illumination beamlets 104 have an angle at the first crossover configured to reduce Coulomb interaction. The first crossover angle can be from approximately 20 to 30 mrad and the second crossover angle can be from approximately 4 to 6 mrad, which is approximately 5× smaller. Thus, the second crossover may dominate the Coulomb interactions.

The manner of creation of telecentric illumination beamlets 104 can affect optical performance for both resolution and throughput. FIG. 3 shows an embodiment that creates and images telecentric illumination beamlets 104 with a field curvature corrector (FCC) 115, an electrode 116 applied with a focusing voltage of VII., and a ground electrode 117 (GND). The field curvature corrector 115 can include two pieces of thin conductive plates separated with a gap distance of tens of microns. One thin conductive plate is at ground and the other has a voltage of V_{FCC} applied. A magnetic field lens (FL) 106 is deployed following the ground electrode 117. The magnetic field lens 106 includes a magnetic pole piece and magnetic coil. The principal plane of the field lens 106 can be used as an intermediate image plane of the electrostatic imaging lens 105 (VII.). In an instance, the field lens 106 can be a magnetic lens with an easy principal plane. The IIP can be formed in the principal plane, such a field lens 106 can adjust the beamlet directions without focusing them.

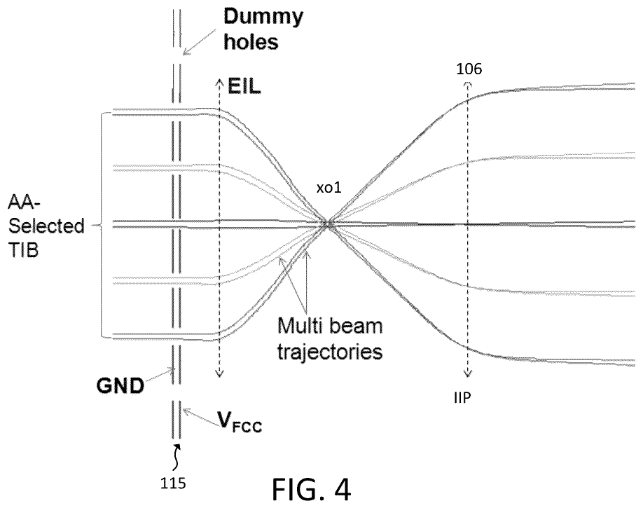

Computer simulations of the electron trajectories are shown in FIG. 4 with respect to the field curvature corrector 115. The FIG. 4 trajectories are the radial-enlarged view (100X) of the multi beam trajectories in FIG. 3. Before doing field curvature correction, the voltage V_{FCC} is zero (ground). For forming the imaging relation shown in FIG. 2 and FIG. 4, the image lens VII. in FIG. 3 is applied with a negative voltage (e.g., approximately −10 to −20 kV for an electron beam with 30 kV energy).

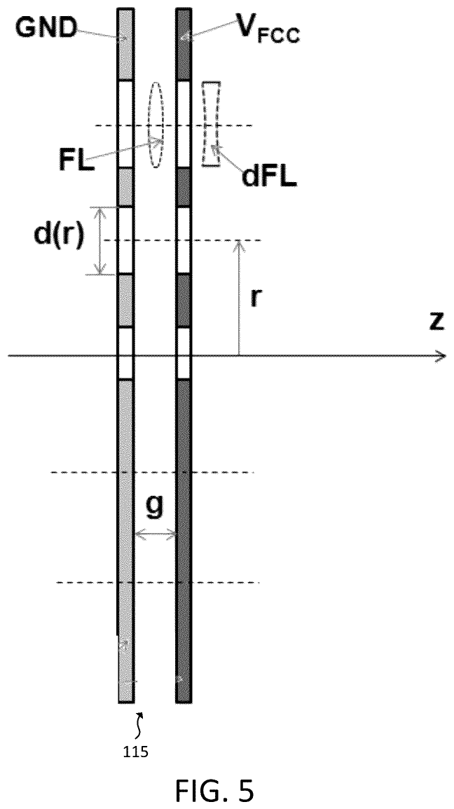

FIG. 5 shows the schematic of the design for correcting the field curvatures. The field curvature corrector 115 includes the ground and V_{FCC} plates separated by a gap distance (g) of tens of microns. The thickness of the two plates may be tens of microns. The bore sizes on the plates (d(r)) can be varied with off-axis distance r.

The field curvature corrector 115 plate, the VII, electrode 116, and the ground electrode 117 in FIG. 3 generate two different lensing effects. One forms a defocusing lens array. When a negative voltage is applied to the image lens VII., the electrostatic field near the bores in the field curvature corrector plate 115 (the plate with the voltage V_{FCC}) forms a defocusing lens array (dFL) because of the decelerating fields penetrated into the field curvature corrector 115 bores, as shown in FIG. 5. The other forms a global focusing lens around the VII, electrode 116 because of the Einzel-lensing effect of the field curvature corrector plate 115, VII, electrode 116, and ground electrodes (including the ground electrode 117). These two lensing effects make it possible to image-form the aperture array-selected telecentric illumination beamlet on the intermediate image plane through forming a crossover xo1, as shown in FIG. 4. Dummy holes can be deployed with the field curvature corrector 115 plates for the field uniformity of the effective holes. With the dummy holes, the electrostatic fields around the active edge-holes are as uniform as the fields around the center-holes, which can provide homogeneous imaging.

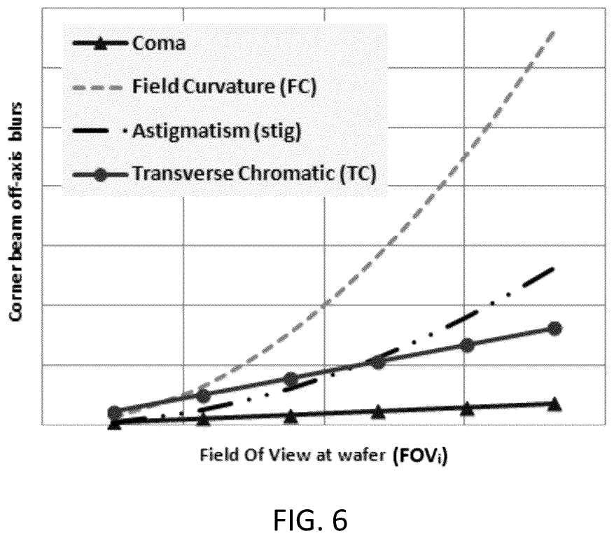

The off-axis blurs described in Equations. (1)-(4) can be simulated. FIG. 6 exhibits the off-axis blurs with the electron beam apparatus in FIGS. 2 and 3. FIG. 6 shows that the field curvature blur is dominant and needs to be first corrected to improve the throughput with larger FOVs. The large-scale electron beamlet deflections by the electrostatic imaging lens (EIL) in FIG. 4 are mostly responsible for the strong FC blur in FIG. 6. Using the magnetic lens can reduce the FCs.

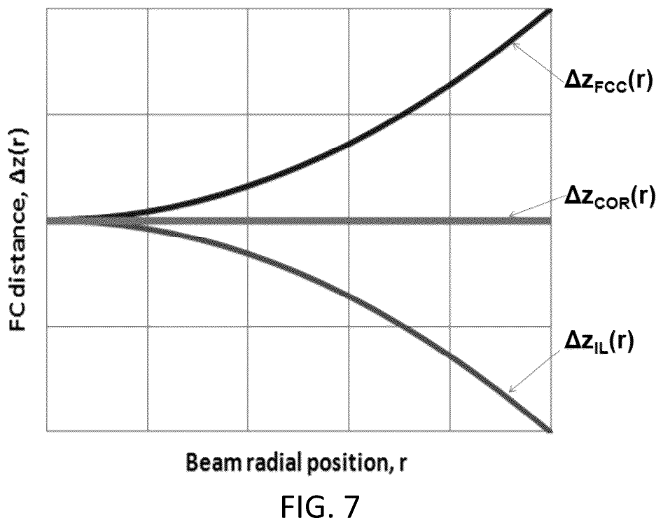

The rationale of correcting the field curvature blur is exhibited in FIG. 5 and FIG. 7. According to the FC blur behavior, the beamlet FC distance at the intermediate image plane, Δz_{IL}(r), is a negatively quadratic function of the off-axis position r (or the beam positions in r-direction), as shown in FIG. 7. When applying an FCC voltage V_{FCC} on the field curvature corrector plate, a micro focusing lens (FL) array is formed in between the ground and field curvature corrector plates, as shown in FIG. 5. The field curvature corrector bore sizes, d (r), in FIG. 5 are designed as quadratic distributions so that the beamlet imaging points at the IIP, Δz_{FCC}(r), are quadratically-varied with the beam positions (r), as shown in FIG. 7. With a field curvature corrector voltage V_{FCC}, the Δz_{FCC}(r) just compensates to the Δz_{IL}(r), and the combined FC distance at intermediate image plane, Δz_{COR}(r), becomes zero to reach the fully correction of the field curvatures. This can occur at from approximately 500-700 V for a 30k V beam energy. This can be approximately 700 V for the use with an electrostatic image lens and approximately 500 V for the use with a magnetic image lens.

The off-axis astigmatism blur in FIG. 6 also affects throughput with larger FOVs. The micro stigmator array 114 (MSA) in FIG. 2 is used to correct the astigmatism in FIG. 6. The micro stigmator array 114 was described in U.S. Pat. No. 11,056,312, the relevant parts of which are incorporated by reference.

The off-axis distortion described in Equation (5) (which is not included in FIG. 6) increases with the FOV. The micro deflector array 113 (MDA) in FIG. 2 can be used to correct the distortion described in Equation (5). The micro deflector array 113 was described in U.S. Pat. No. 10,748,739, the relevant parts of which are incorporated by reference.

After the FC and astigmatism blurs are corrected in FIG. 6, the transverse chromatic (TC) blur is dominant when addressing throughput improvement with larger FOVs. Full correction of the lensing-induced TC blur may not be possible, but the TC blur can be largely reduced.

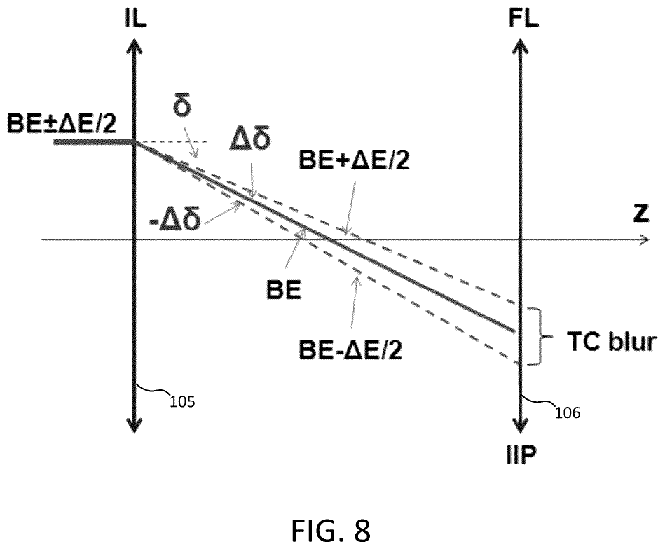

Taking one principal trajectory in FIG. 2 for example, the electron beam energy (BE) (e.g., 30 keV) can be varied with BE±ΔE/2 because the electron emission source (e.g., a TFE source) may have an energy spread of ΔE (e.g., ΔE=1eV). When the electrons with energies of BE+ΔE/2 enter into the image lens field, they are deflected an angle of δ+Δδ, in which the Δδ characterizes the image lens energy dispersion and generates the TC blur in the intermediate image plane, as can be shown in FIG. 8. The lens deflection angles in FIG. 8 are δ_{E}˜1/BE with an electrostatic lensing field and δ_{M}˜1/√BE with a magnetic lensing field. Furthermore, it exhibits a relation shown in Equation (6).

$${Δδ}_{E} = 2 {Δδ}_{M} \qquad ( 6 )$$

Equation (6) suggests that the energy dispersion angle with the electrostatic lensing field (Δδ_{E}) is 2× larger than that with a magnetic lensing field (48M). Thus, the TC blur induced by an electrostatic lensing field is 2× larger than that by a magnetic lensing field.

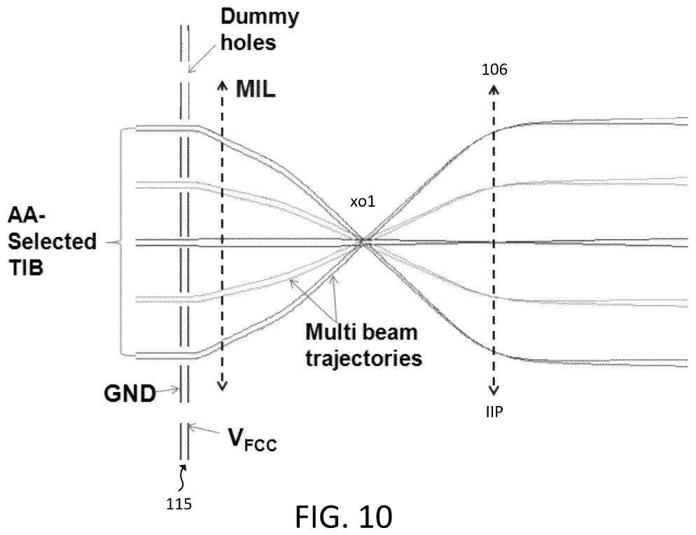

FIG. 9 shows an embodiment with a magnetic imaging lens 105 (MIL) in the optics of FIG. 2. The field curvature corrector 115 (FCC) and field lens 106 (FL) are the same as those in FIG. 3. Following the field curvature corrector 115, an electrode applied with a fixed voltage (V_{MBS}) is used. The V_{MBS} electrode is referred to as a multi-beam splitter 118 (MBS), by which the same defocusing lens array (dFL) in FIG. 5 is formed with a negative voltage of the multi beam splitter 118 (e.g., V_{MBS}=−4 kV for 30 kV beams). The magnetic imaging lens 105 (MIL) is a global focusing lens, and all the telecentric illumination beamlets generated from the field curvature corrector bores and the multi beam splitter fields are collectively focused (image-formed) in the intermediate image plane. The intermediate image plane is still located in the principal plane of the field lens (FL). The magnetic imaging lens 105 (MIL) includes the pole pieces and coils as shown in FIG. 9. FIG. 10 shows the radial-enlarged multi beam trajectories in FIG. 9, exhibiting similar optics than FIG. 4.

Thus, when the imaging lens 105 is a magnetic imaging lens, a fixed voltage electrode can be disposed in the path of the telecentric illumination beamlets 104 between the field curvature corrector 115 and the magnetic imaging lens 105. A multi-beam splitter electrode 118 can be disposed in the path of the telecentric illumination beamlets 104 between the fixed voltage electrode and the magnetic imaging lens 105.

FIG. 1 can include the multiple electron beam array either in the wafer plane with FOVᵢ or in the intermediate image plane (IIP) with FOVₒ, as shown in FIG. 2. The optical magnification from FOVₒ to FOVᵢ may be, for example 0.1×.

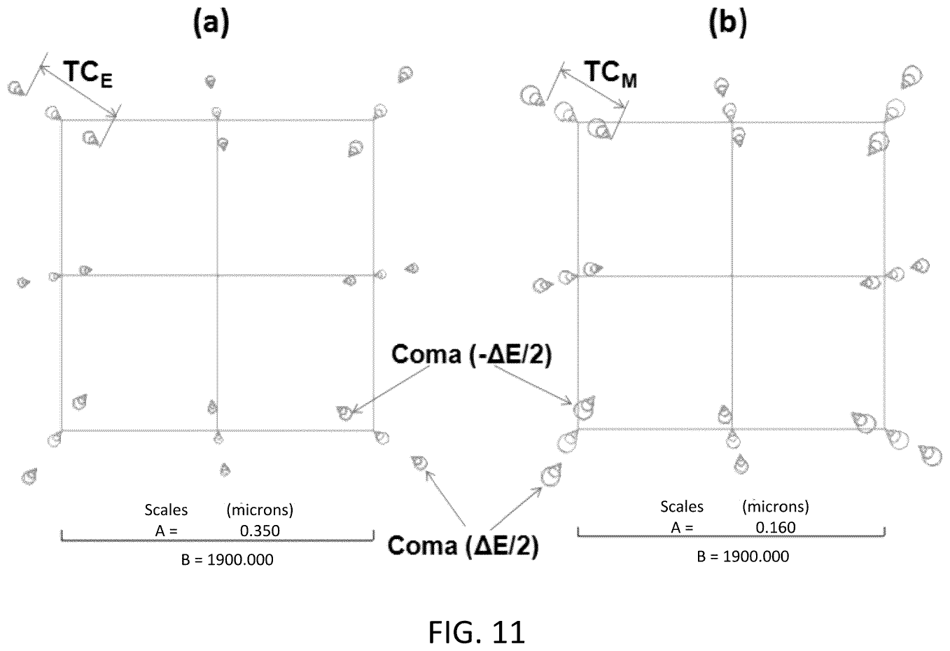

Computer simulations can be used to determine all the beamlet spot sizes and various components of the spot sizes either with FOVₒ in the IIP or with FOVᵢ in the workpiece. For example, FIG. 11(a)-(b) exhibits the TC and coma blurs with FOVₒ in the IIP. The TC and coma are described in Equation (1) and Equation (4) with FOVₒ to replace FOVᵢ and with a to replace β in FIG. 2. In the IIP, the FOVₒ is 1900×1900 microns for a 400 beamlet array with a pitch of 100 microns. FIG. 11 shows the TC and coma blurs in the four farthest corners of FIG. 1. With Equations (1) and (4), the TC and coma blurs for any beamlet in FIG. 1 can be determined through scaling.

In FIG. 11(a)-(b), the blur size and FOV size are scaled by A and B, respectively. FIG. 11(a) has TC and coma in the IIP with an EIL. FIG. 11(b) has TC and coma in the IIP with a magnetic imaging lens.

FIGS. 11(a) and 11(b) exhibit the TC blur and coma blur for the optics with an electrostatic imaging lens (EIL) and magnetic imaging lens (MIL) for the imaging lens 105, respectively. Note that the FOV scale (the B scale) is identical between FIGS. 11(a) and 11(b), but the aberration blur scale (the A scale) is different between FIGS. 11(a) and 11(b). According to the scaling, the TC_{E} (the TC blur with an electrostatic imaging lens) is 91 nm, and the TC_{M} (the TC blur with a magnetic imaging lens) is 36 nm. The TC_{M} is 2.5× smaller than the TC_{E}, showing that a magnetic imaging lens can provide improved results in certain situations compared to an EIL when improving the machine throughputs with larger FOVs. For a 400 beam array with a pitch of 100 microns in the IIP, the coma blur is relatively small and negligible according to the scaling in FIGS. 11(a) and 11(b) considering the coma blur would even be 10X smaller in the workpiece than in the IIP with an optical magnification of 10X.

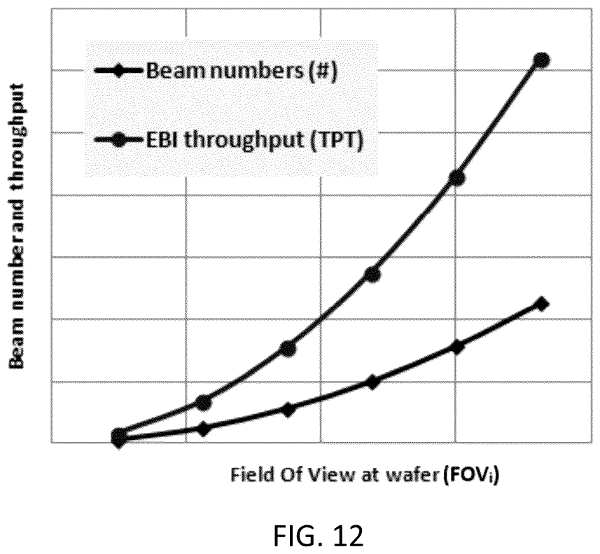

FIG. 12 shows the throughput scaling trend for multiple electron beam inspections (MEBI). The telecentric illumination beamlets 104 may be arranged as either a square distribution like FIG. 1, a hexagon distribution, or other distributions. Both the EBI throughput and MB numbers increase with the FOV quadratically.

The off-axis astigmatism blurs and distortions can be corrected separately with independent correctors (micro stigmator array and micro deflector array, respectively) for each individual telecentric illumination beamlet 104. The off-axis FC (field curvature) blurs can be corrected with an FCC voltage together with quadratically-variable FCC holes. The off-axis TC (transverse chromatic) blurs may be physically uncorrectable, but may be reduced by replacing the electrostatic lenses with magnetic lenses in the optical architectures like FIG. 2. Besides designing the imaging lens 105 (IL) and field lens 106 (FL) as magnetic lenses, the transfer lens 107 and objective lens 110 also can be designed as magnetic lenses.

When inspecting a workpiece, a telecentric electron beam can be generated with an electron source, such as the telecentric electron beam 102 shown in FIG. 2. The telecentric electron beam can be directed through an array of apertures. The array of apertures is configured to divide the telecentric electron beam to a plurality of telecentric illumination beamlets. The telecentric illumination beamlets can be directed through an imaging lens downstream of the array of apertures and a field lens downstream of the imaging lens along the path of the telecentric illumination beamlets. The field lens is at an intermediate image plane. The telecentric illumination beamlets can be directed through a transfer lens disposed downstream of the field lens along the path of the telecentric illumination beamlets. The telecentric illumination beamlets can be scanned as the electron beams are directed through an upper scan deflector and a lower scan deflector disposed downstream of the transfer lens along the path of the telecentric illumination beamlets. Then the telecentric illumination beamlets can be directed onto a workpiece on a stage disposed downstream of the lower scan deflector along the path of the telecentric illumination beamlets. In an instance, transfer lens is a magnetic lens, such as one with two coils inside the pole pieces. The two coils may have opposite current polarities for being able to adjust the image rotations (i.e., the orientation of the beam array in FIG. 1).

In an instance, the telecentric illumination beamlets can be directed through a micro deflector array downstream of the array of apertures along the path of the telecentric illumination beamlets. The telecentric illumination beamlets can be directed through a micro stigmator array downstream of the micro deflector array along the path of the telecentric illumination beamlets. The telecentric illumination beamlets can be directed through a field curvature corrector downstream of the micro stigmator array along the path of the telecentric illumination beamlets. The field curvature corrector is disposed upstream of the imaging lens along the path of the telecentric illumination beamlets.

The field curvatures caused by the image lens can be corrected using the field curvature corrector. The field curvatures caused by the transfer lens, the upper scan deflector, and the lower scan deflector can be corrected using the field curvature corrector.

In an instance, the telecentric illumination beamlets are configured to have a first crossover along the path of the telecentric illumination beamlets between the imaging lens and the field lens and a second crossover along the path of the telecentric illumination beamlets between the lower scan deflector and the stage. The telecentric illumination beamlets can have an angle at the first crossover configured to reduce Coulomb interaction.

In an instance, the imaging lens is a magnetic imaging lens. The telecentric illumination beamlets are directed through a fixed voltage electrode disposed in the path of the telecentric illumination beamlets between the field curvature corrector and the magnetic imaging lens. The telecentric illumination beamlets are directed through a multi-beam splitter electrode disposed in the path of the telecentric illumination beamlets between the fixed voltage electrode and the magnetic imaging lens.

The telecentric illumination beamlets can have an off-axis blur of less than 5 nm after the FC blur and astigmatism blur are corrected, such as with an field curvature corrector and micro stigmator array. The TC blur can be reduced with a magnetic imaging lens because the telecentric illumination beamlets are directed onto the workpiece. This effect can be measured as the telecentric illumination beamlets are directed onto the workpiece.

The telecentric illumination beamlets can have a distortion of less than one pixel size after the electron trajectory displacements are corrected with an micro deflector array. This can be measured as the telecentric illumination beamlets are directed onto the workpiece.

The telecentric illumination beamlets can be focused on the intermediate image plane using global electrostatic fields or global magnetic fields.

While disclosed with electron beams, the embodiments disclosed herein can apply to other charged particles beams. Thus, ion beams (e.g., helium ion beams) also can benefit from the embodiments disclosed herein. The source can be an electron beam source, an ion beam source, or other devices.

Although the present disclosure has been described with respect to one or more particular embodiments, it will be understood that other embodiments of the present disclosure may be made without departing from the scope of the present disclosure. Hence, the present disclosure is deemed limited only by the appended claims and the reasonable interpretation thereof.

What is claimed is:

1. An apparatus comprising:
a source that generates a telecentric charged particle beam;
a stage configured to hold a workpiece in a path of a plurality of telecentric illumination beamlets;
an array of apertures disposed in a path of the telecentric charged particle beam between the source and the stage, wherein the array of apertures is configured to divide the telecentric charged particle beam into the plurality of telecentric illumination beamlets;
a field lens disposed in the path of the telecentric illumination beamlets at an intermediate image plane;
a transfer lens disposed in the path of the telecentric illumination beamlets between the field lens and the stage;
an imaging lens disposed in the path of the telecentric illumination beamlets between the source and the field lens;
an upper scan deflector disposed in the path of the telecentric illumination beamlets between the transfer lens and the stage; and
a lower scan deflector disposed in the path of the telecentric illumination beamlets between the upper scan deflector and the stage, wherein the upper scan deflector and the lower scan deflector are configured to scan the telecentric illumination beamlets.

2. The apparatus of claim 1, further comprising:
a micro deflector array disposed in the path of the telecentric illumination beamlets between the array of apertures and the imaging lens;
a micro stigmator array disposed in the path of the telecentric illumination beamlets between the micro deflector array and the imaging lens; and
a field curvature corrector disposed in the path of the telecentric illumination beamlets between the micro stigmator array and the imaging lens.

3. The apparatus of claim 1, wherein the telecentric illumination beamlets are configured to have a first crossover along the path of the telecentric illumination beamlets between the imaging lens and the field lens, and wherein the telecentric illumination beamlets are configured to have a second crossover along the path of the telecentric illumination beamlets between the lower scan deflector and the stage.

4. The apparatus of claim 3, wherein the telecentric illumination beamlets have an angle at the first crossover configured to reduce Coulomb interaction.

5. The apparatus of claim 1, wherein the field lens is a magnetic field lens.

6. The apparatus of claim 5, wherein the imaging lens is a magnetic imaging lens, and further comprising a fixed voltage electrode disposed in the path of the telecentric illumination beamlets between the field curvature corrector and the magnetic imaging lens and a multi-beam splitter electrode disposed in the path of the telecentric illumination beamlets between the fixed voltage electrode and the magnetic imaging lens.

7. The apparatus of claim 1, wherein the telecentric illumination beamlets are focused on the intermediate image plane using global electrostatic fields or global magnetic fields.

8. The apparatus of claim 1, wherein the telecentric charged particle beam is a telecentric electron beam and the source is an electron beam source.

9. A method of inspecting a workpiece comprising:
generating a telecentric charged particle beam with a source;
directing the telecentric charged particle beam through an array of apertures, wherein the array of apertures is configured to divide the telecentric charged particle beam to a plurality of telecentric illumination beamlets;
directing the telecentric illumination beamlets through an imaging lens downstream of the array of apertures along a path of the telecentric illumination beamlets;
directing the telecentric illumination beamlets through a field lens downstream of the imaging lens along the path of the telecentric illumination beamlets, wherein the field lens is at an intermediate image plane;
directing the telecentric illumination beamlets through a transfer lens disposed downstream of the field lens along the path of the telecentric illumination beamlets;
scanning the telecentric illumination beamlets as the telecentric illumination beamlets are directed through an upper scan deflector and a lower scan deflector disposed downstream of the transfer lens along the path of the telecentric illumination beamlets; and
directing the telecentric illumination beamlets onto a workpiece on a stage disposed downstream of the lower scan deflector along the path of the telecentric illumination beamlets.

10. The method of claim 9, further comprising:
directing the telecentric illumination beamlets through a micro deflector array downstream of the array of apertures along the path of the telecentric illumination beamlets;
directing the telecentric illumination beamlets through a micro stigmator array downstream of the micro deflector array along the path of the telecentric illumination beamlets; and
directing the telecentric illumination beamlets through a field curvature corrector downstream of the micro stigmator array along the path of the telecentric illumination beamlets, wherein the field curvature corrector is disposed upstream of the imaging lens along the path of the telecentric illumination beamlets.

11. The method of claim 10, further comprising correcting field curvatures caused by the image lens using the field curvature corrector.

12. The method of claim 10, further comprising correcting field curvatures caused by the transfer lens, the upper scan deflector, and the lower scan deflector using the field curvature corrector.

13. The method of claim 9, wherein the telecentric illumination beamlets are configured to have a first crossover along the path of the telecentric illumination beamlets between the imaging lens and the field lens, and wherein the telecentric illumination beamlets are configured to have a second crossover along the path of the telecentric illumination beamlets between the lower scan deflector and the stage.

14. The method of claim 13, wherein the telecentric illumination beamlets have an angle at the first crossover configured to reduce Coulomb interaction.

15. The method of claim 9, wherein the field lens is a magnetic field lens.

16. The method of claim 15, wherein the imaging lens is a magnetic imaging lens, and further comprising:
directing the telecentric illumination beamlets through a fixed voltage electrode disposed in the path of the telecentric illumination beamlets between the field curvature corrector and the magnetic imaging lens; and
directing the telecentric illumination beamlets through a multi-beam splitter electrode disposed in the path of the telecentric illumination beamlets between the fixed voltage electrode and the magnetic imaging lens.

17. The method of claim 9, wherein the telecentric illumination beamlets have an off-axis blur of less than 5 nm as the telecentric illumination beamlets are directed onto the workpiece.

18. The method of claim 9, wherein the telecentric illumination beamlets have a distortion of less than one pixel size as the telecentric illumination beamlets are directed onto the workpiece.

19. The method of claim 9, wherein the telecentric illumination beamlets are focused on the intermediate image plane using global electrostatic fields or global magnetic fields.

20. The method of claim 9, wherein the telecentric charged particle beam is a telecentric electron beam and the source is an electron beam source.
